(19) United States
(12) Patent Application Publication
(10) Pub. No.: US 2025/0056807 A1
(43) Pub. Date: Feb. 13, 2025

(54) SEMICONDUCTOR DEVICES

(71) Applicant: Samsung Electronics Co., Ltd., Suwon-si (KR)

(72) Inventors: Juseong Min, Suwon-si (KR); Jaebok Baek, Suwon-si (KR); Taekkyu Yoon, Suwon-si (KR); Jeehoon Han, Suwon-si (KR)

(21) Appl. No.: 18/790,129

(22) Filed: Jul. 31, 2024

(30) Foreign Application Priority Data
Aug. 11, 2023 (KR) 10-2023-0105423

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device includes a substrate, active regions extending on the substrate in a first direction, the active regions spaced apart from each other in a second direction perpendicular to the first direction, and arranged in a third direction oblique to the first direction and second direction, and gate electrodes disposed on the active regions and including a first edge extending in the second direction, a second edge extending in the first direction, and a corner region defined by the first edge and the second edge, wherein the corner region includes a protrusion having a width narrowing in a direction away from a center of each of the gate electrodes in plan view.

### CROSS-REFERENCE TO RELATED APPLICATION(S)

This application claims benefit of priority under 35 U.S.C. § 119 to Korean Patent Application No. 10-2023-0105423 filed on Aug. 11, 2023 in the Korean Intellectual Property Office, the disclosure of which is incorporated herein by reference in its entirety.

### BACKGROUND

The present inventive concept relates generally to a semiconductor device, and, more particularly, to a semiconductor device having increased integration and reliability.

As demand for high performance, speed, and/or multifunctionality of electronic devices has increased, high integration of semiconductor devices within electronic devices has been required.

### SUMMARY

An aspect of the present inventive concept is to provide a semiconductor device having increased integration and reliability.

According to an aspect of the present inventive concept, a semiconductor device includes a substrate, active regions extending on the substrate in a first direction, the active regions spaced apart from each other in a second direction perpendicular to the first direction, and arranged in a third direction oblique to the first direction and second direction, and gate electrodes disposed on the active regions and including a first edge extending in the second direction, a second edge extending in the first direction, and a corner region defined by the first edge and the second edge, wherein the corner region includes a protrusion having a width narrowing in a direction away from a center of each of the gate electrodes in plan view.

According to an aspect of the present inventive concept, a semiconductor device includes a substrate, active regions extending on the substrate in a first direction, the active regions spaced apart from each other in a second direction perpendicular to the first direction, and arranged in a third direction oblique to the first direction and second direction, gate electrodes arranged in the third direction on the active regions, a groove disposed between the gate electrodes adjacent to each other in the third direction and extending in the first direction, and a spacer layer filling at least a portion of the groove and surrounding sides of the gate electrodes.

According to an aspect of the present inventive concept, a semiconductor memory device includes: a memory cell region including memory cells arranged on a plate layer, and a peripheral circuit region disposed to be adjacent to the memory cell region and including transistors electrically connected to the memory cells, wherein the transistors include active regions extending in a first direction on a substrate, the active regions spaced apart from each other in a second direction perpendicular to the first direction, and arranged in a third direction oblique to the first direction and second direction, gate electrodes disposed on the active regions and including a corner region having at least one protrusion protruding in a direction, parallel to the first direction, and a spacer layer surrounding the gate electrodes and having a wave shape in plan view.

### BRIEF DESCRIPTION OF DRAWINGS

The above and other aspects, features, and advantages of the present inventive concept will be more clearly understood from the following detailed description, taken in conjunction with the accompanying drawings, wherein like reference numerals (when used) indicate corresponding elements throughout the several views, and in which:

FIG. 1 is a schematic plan view of a semiconductor device according to example embodiments;

FIGS. 2A to 2C are schematic cross-sectional views of a semiconductor device according to example embodiments;

FIGS. 3A and 3B are schematic partially enlarged views of a semiconductor device according to example embodiments;

FIGS. 4A to 6B are schematic plan views and corresponding cross-sectional views taken along line III-III′ illustrating a method of manufacturing a semiconductor device according to example embodiments;

FIG. 7 is a schematic block diagram of a semiconductor device according to example embodiments;

FIG. 8 is a perspective schematic layout diagram illustrating a semiconductor device according to example embodiments; and

FIG. 9 is a schematic cross-sectional view of a semiconductor device according to example embodiments.

### DETAILED DESCRIPTION

Hereinafter, preferred embodiments of the present inventive concept will be described with reference to the attached drawings. Unless otherwise specified, in this specification, terms, such as ‘upper portion’, ‘upper surface’, ‘lower portion, ‘lower surface, ‘side surface’, etc. are based on the drawings and may actually vary depending on a direction and/or orientation in which the components are arranged.

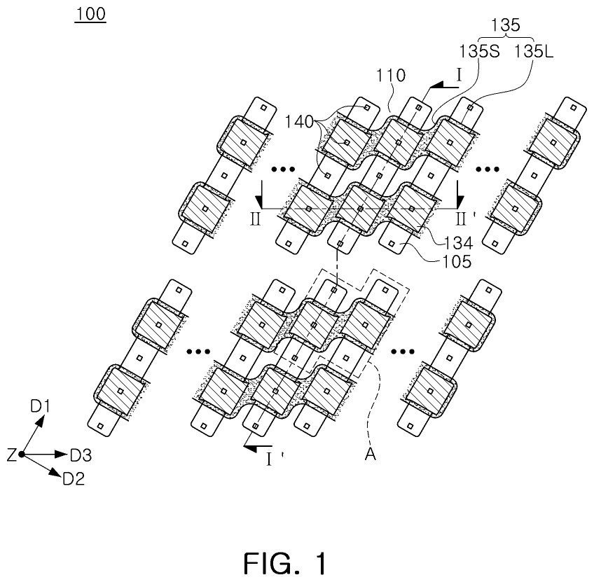

FIG. 1 is a schematic plan view of a semiconductor device according to example embodiments.

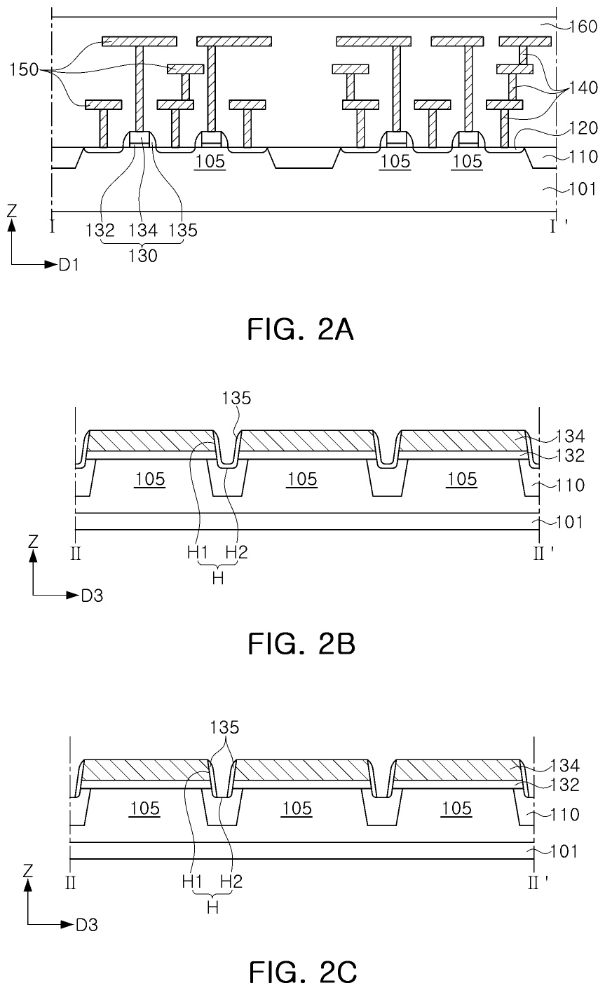

FIGS. 2A and 2B are schematic cross-sectional views of a semiconductor device according to example embodiments. FIGS. 2A and 2B are cross-sectional views taken along lines I-I′ and II-II′ of FIG. 1, respectively.

Referring to FIGS. 1, 2A, and 2B, a semiconductor device 100 may include a substrate 101, active regions 105 within the substrate 101, device isolation regions 110 within the substrate 101, source/drain regions 120 within the active regions 105, circuit elements 130 disposed on the substrate 101, an insulating layer 160, circuit contact plugs 140, and circuit interconnection lines 150.

The substrate 101 may have an upper surface extending in a horizontal direction. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, or a semiconductor-on-insulator (SeOI) layer.

The active regions 105 may be defined within the substrate 101 and may extend in a first direction D1 parallel to the upper surface of the substrate 101 and be separated from one another in a second direction D2 parallel to the upper surface of the substrate 101 and orthogonal to the first direction D1. The active regions 105 may include the same or different types of impurities as the substrate 101 at the same or different concentration levels. For example, the impurity may be an N-type impurity or a P-type impurity depending on the function of the circuit elements 130.

The device isolation regions 110 may define the active regions 105 in the substrate 101. The device isolation regions 110 may be formed of an insulating material. The device isolation regions 110 may be, for example, oxide, nitride, or combinations thereof. The device isolation regions 110 may be formed by, for example, a shallow trench isolation (STI) process.

The source/drain regions 120 may be disposed in the active regions 105 of the substrate 101 on both sides of the circuit elements 130, proximate the upper surface of the substrate 101. Each of the source/drain regions 120 may serve as a source region or a drain region of the circuit elements 130. The source/drain regions 120 may include a different type of impurity than the adjacent active regions 105.

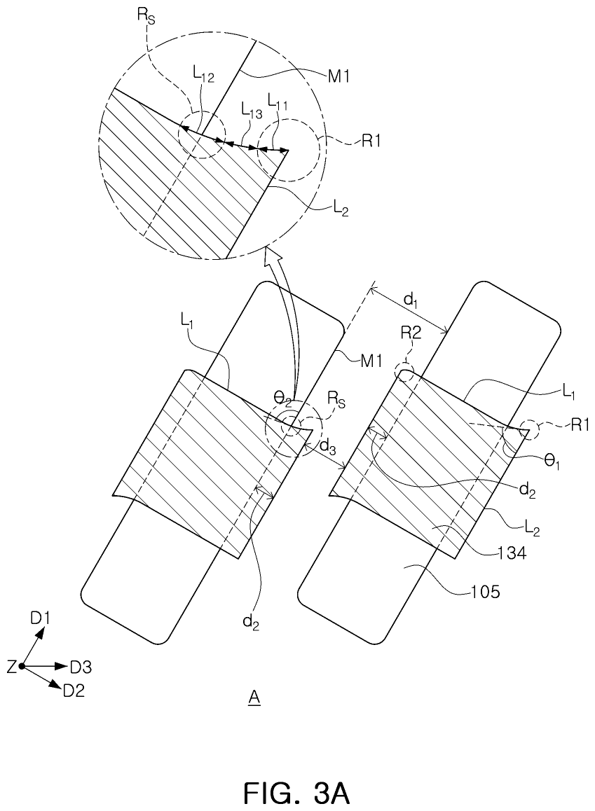

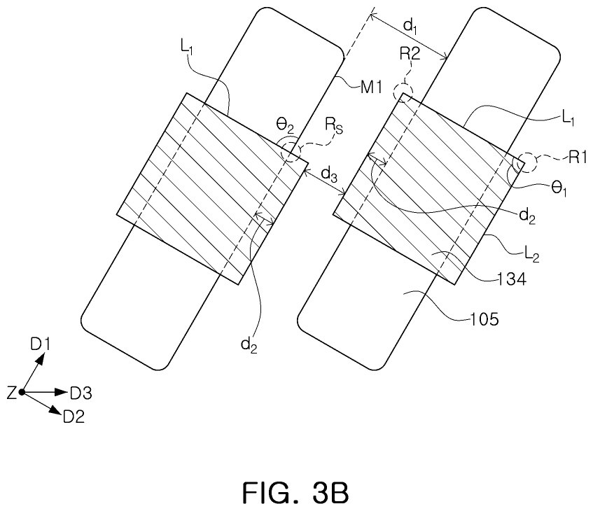

The active regions 105 may be defined by the device isolation regions 110 on the substrate 101 and arranged in a third direction D3 intersecting the first and second directions D1, D2 (e.g., diagonally). As illustrated in FIG. 1, the active regions 105 may extend in the first direction D1 on the substrate 101. The device isolation regions 110 extending in the first direction D1 may be arranged between the active regions 105. The active regions 105 may be arranged to be spaced apart from each other by a first distance d₁ (refer to FIG. 3A) in the second direction D2, perpendicular to the first direction D1, by the device isolation regions 110. The active regions 105 may be arranged in the third direction D3 that is oblique to the first direction D1 and the second direction D2. Accordingly, the circuit elements 130 disposed on the active regions 105 may be arranged in the third direction D3. As the active regions 105 are arranged diagonally on the substrate 101, the pitch of the active regions 105 in a predetermined direction (e.g., the third direction D3) on the substrate 101 may be reduced.

Each of the circuit elements 130 may include a planar transistor. As illustrated in FIG. 2A, each circuit element 130 may include a circuit gate dielectric layer 132, a circuit gate electrode 134 on the circuit gate dielectric layer 132, and a spacer layer 135 on sidewalls of the gate electrode 134 and circuit gate dielectric layer 132.

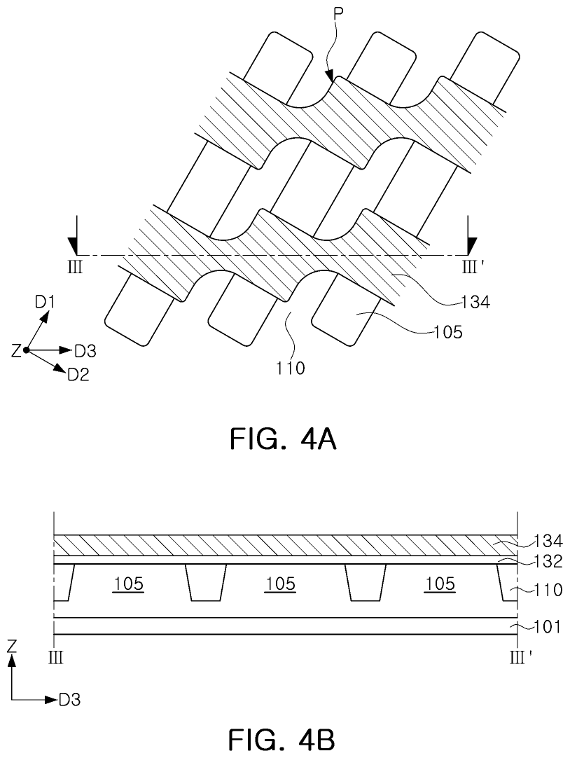

The circuit elements 130 may be disposed on the active regions 105 and may be arranged in the third direction D3. Each of the circuit gate electrodes 134 (or ‘circuit gate dielectric layers 132’) may be arranged to be spaced apart from each other by a groove H. The groove H may be disposed in at least a portion between the active regions 105 and may extend in the first direction D1. Accordingly, the circuit gate electrodes 134 (or the ‘circuit gate dielectric layers 132’) may be spaced apart from each other by a third distance d₃ (refer to FIG. 4B) in the second direction D2 by the groove H. As the active regions 105 are disposed diagonally on the substrate 101, the pitch of the circuit elements 130 disposed on the active regions 105 in a predetermined direction (e.g., D2) may also be reduced. Accordingly, since the groove H is disposed in at least a portion between the active regions 105 and isolates the circuit elements 130, in particular, the circuit gate electrodes 134, in the predetermined direction (for example, the second direction D2), a semiconductor device having increased integration and reliability is provided.

A bottom level (i.e., lower surface H2) of the groove H may be substantially equal to or lower than a bottom level of the circuit gate dielectric layers 132 (or a ‘top level of the active region 105’). Referring to FIG. 4B, the uppermost portion of the groove H may have a first width W in the second direction D2, and the horizontal width in the second direction D2 may become narrower as the groove H extends downwardly in a vertical direction Z perpendicular to the upper surface of the substrate 101. The first width W may be substantially equal to the third distance d₃ by which the circuit gate electrodes 134 are spaced apart from each other in the second direction D2 (refer to FIG. 4B).

The spacer layer 135 may be disposed on sidewalls of circuit gate dielectric layer 132 and the circuit gate electrode 134; that is, spacer layer 135 may extend around sides of the circuit gate dielectric layer 132 and the circuit gate electrode 134. As illustrated in FIG. 1, the spacer layer 135 may have a wave type shape when viewed in plan view. Specifically, in plan view, side surfaces of the spacer layer 135 in the first direction D1 may have wave shapes corresponding to each other.

The spacer layer 135 may have a straight portion 135L extending in the second direction D2 along the sidewall of the gate electrode 134 on the active region 105. The spacer layer 135 may fill at least a portion of the groove H between the active regions 105. The term “fill” (or “filling,” “filled,” or like terms), as may be used herein, is intended to refer broadly to either completely filling a defined space (e.g., the groove H) or partially filling the defined space; that is, the defined space need not be entirely filled but may, for example, be partially filled or have voids or other spaces throughout. As illustrated in FIG. 2B, the spacer layer 135 may be disposed on a sidewall H1 of the groove and may cover a lower surface H2 of the groove H. The term “cover” (or “covering,” or like terms), as may be used herein, is intended to broadly refer to an element, structure or layer that is on or over another element, structure or layer, either directly or with one or more other intervening elements, structures or layers therebetween.

The spacer layer 135 may have a curved portion 135S between the active regions 105. The curved portion 135S may connect the straight portions 135L disposed on the active regions 105 between the active regions 105; adjacent straight portions 135S of the spacer layer 135 may be offset at different levels in the first direction D1. The spacer layer 135 may have a continuous shape extending in the third direction D3.

The insulating layer 160 may be disposed on the circuit elements 130 on the substrate 101. The insulating layer 160 may include a plurality of insulating layers formed in different process operations. The insulating layer 160 may be formed of an insulating material.

The circuit contact plugs 140 and circuit interconnection lines 150 may form a circuit interconnection structure electrically connected to the circuit elements 130 and the source/drain regions 120. The circuit contact plugs 140 may have a cylindrical shape extending in the vertical direction Z, and the circuit interconnection lines 150 may have a line shape extending in a horizontal direction (e.g., direction D1, D2 and/or D3) parallel to the upper surface of the substrate 101. An electrical signal may be applied to the circuit element 130 by the circuit contact plugs 140 and circuit interconnection lines 150. The circuit interconnection lines 150 may be connected to the circuit contact plugs 140, may have a line shape, and may be arranged in multiple layers. The term “connected” (or “connecting,” “contact,” “contacting,” or like terms), as may be used herein, is intended to refer to a physical and/or electrical connection between two or more elements, and may include other intervening elements. As used herein, the term “and/or” includes any and all combinations of one or more of the associated listed items. The circuit contact plugs 140 and circuit interconnection lines 150 may include a conductive material, for example, tungsten (W), copper (Cu), aluminum (Al), etc., and each component may further include a diffusion barrier (not explicitly shown). In example embodiments, the number of layers of the circuit contact plugs 140 and circuit interconnection lines 150 may vary.

FIG. 2C is a schematic cross-sectional view of a semiconductor device according to example embodiments. FIG. 2C illustrates a cross-section taken along line II-II′ of FIG. 1.

Referring to FIG. 2C, the semiconductor device of an embodiment is the same or similar to that described above with reference to FIGS. 1, 2A, and 2B, except that the spacer layer 135 covers only a portion of the lower surface H2 of the groove H.

In the present embodiment, the spacer layer 135 may be disposed on a sidewall H1 of the groove and may cover only a portion of the lower surface H2 of the groove. Accordingly, a portion of the lower surface H2 of the groove H may be exposed through the groove H. The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

As the spacer layer 135 is disposed only on a portion of the lower surface H2 of the groove, the spacer layer 135 may have a discontinuous shape between adjacent circuit elements 130. For example, when the lower surface H2 of the groove H is discontinuously exposed between the circuit elements 130, the spacer layer 135 may not have a continuous shape between the circuit elements 130. Alternatively, when the exposed portion of the lower surface H2 of the groove H is continuously disposed in the first direction D1, the spacer layer 135 may be configured as a plurality of spacer layers. Each of the plurality of spacer layers may be arranged to be spaced apart from each other in the second direction D2.

FIG. 3A is a schematic partially enlarged view of a semiconductor device according to example embodiments. Specifically, FIG. 3A illustrates an enlarged plan view of region ‘A’ in FIG. 1.

Referring to FIG. 3A, the active regions 105 may be arranged diagonally on the substrate 101. The active regions 105 may extend in the first direction D1 on the substrate, may be arranged to be spaced apart from each other by the first distance d₁ in the second direction D2, perpendicular to the first direction D1, and may be arranged in the third direction D3, oblique to (i.e., intersecting) the first direction D1 and the second direction D2. The first distance d₁ may be about 60 nanometers (nm) or less, for example, 40 nm to 60 nm, 45 nm to 55 nm, or 45 nm to 50 nm.

The gate electrode 134 may be disposed on the active regions 105. The gate electrode 134 may include a first edge L₁ extending in the second direction D2 on the active regions 105, a second edge L₂ extending in the first direction D1 outside the active regions 105, and a first corner region R1 and a second corner region R2 at which the first edge L₁ and the second edge L₂ meet; that is, the first corner R1 and the second corner R2 may be defined by an intersection of the first edge L₁ and the second edge L₂. The first corner region R1 and the second corner region R2 may be disposed outside the active regions 105. The first corner region R1 may have a protrusion having a width narrowing in a direction away from the center of the gate electrode 134 when viewed in a plan view. For example, the protrusion may have a shape having a sharp portion, and the sharp portion may face in a direction, parallel to the first direction D1. The second corner region R2 may have a rounder shape than the first corner region R1.

The gate electrode 134 may have an intersection region Rs. In the intersection region Rs, the first edge L₁ extending in the second direction D2, may cross a first active edge M1 extending in the first direction D1, among the edges of the active regions 105.

At least a portion of the first edge L₁ may include a curved portion. The curved portion may extend from the intersection region Rs to the first corner region R1 (or the ‘second corner region R2’). For example, the curved portion may include a second curved portion L₁₂ in the intersection region Rs, a first curved portion Lu in the first corner region R1, and a third curved portion L₁₃ extending from the intersection region Rs to the first corner region R1. A slope of the curved portion of the first edge L₁ may increase in a direction from the intersection region Rs to the first corner region R1 (or the ‘second corner region R2’). For example, the third curved portion L₁₃ may be steeper (i.e., having a greater slope relative to a slope of the first edge L₁ outside of the intersection region Rs) than the second curved portion L₁₂, and the first curved portion L₁₁ may be steeper than the third curved portion L₁₃. In the first corner region R1, the first curved portion Lu of the first corner R1 may meet the second edge L₂. In the first corner region R1, a tangent line of the first curved portion Lu may form a first angle θ1 with the second edge L₂. The first angle θ1 may be an acute angle less than 90 degrees. In the intersection region Rs, the second curved portion L₁₂ of the first edge L₁ may meet the first active edge M1. In the intersection region Rs, a tangent line of the second curved portion L₁₂ may form a second angle θ2 with the first active edge M1. The second angle θ2 may be an obtuse angle exceeding 90 degrees.

A portion of the gate electrode 134 may be disposed outside the active region 105 in the second direction D2. The second edge L₂ of the gate electrode 134 may be disposed outside of the active region 105 (i.e., extend beyond the first active edge of the active region 105) by a second distance d₂ in the second direction D2, from the first active edge M1 of the active regions 105. The second distance d₂ may be about 20 nm or less, for example, 10 nm to 20 nm, or 15 nm to 20 nm.

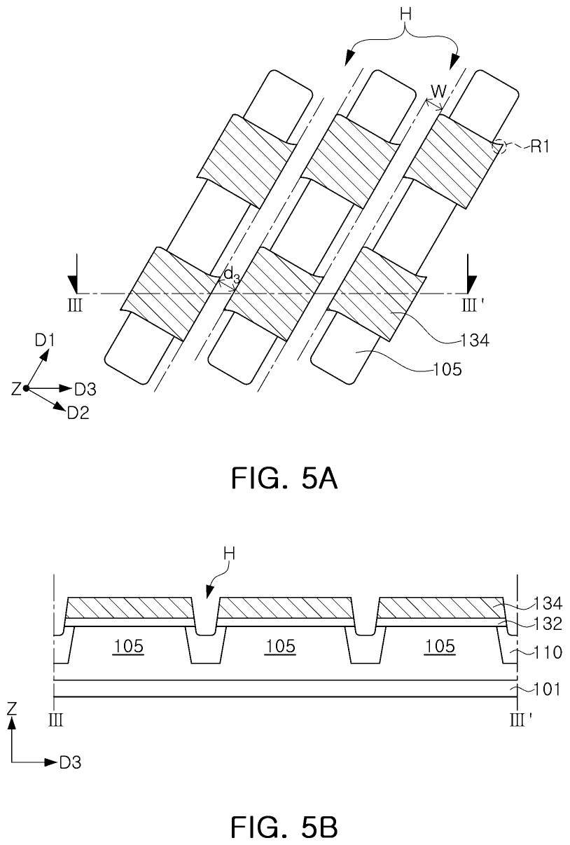

The gate electrodes 134 adjacent in the second direction D2 may be arranged to be spaced apart by a third distance d₃ in the second direction D2. The third distance d₃ may be about 40 nm or less, for example, 10 nm to 40 nm, 15 nm to 30 nm, or 15 nm to 20 nm. Referring to FIG. 5A together, the groove H may be disposed between the gate electrodes 134 spaced apart from each other in the second direction D2 and extend in the first direction D1. Similarly, referring to FIG. 5A together, the uppermost portion of the groove H may have a first width W, which is a horizontal width in the second direction D2. The first width W may be substantially equal to the third distance d₃.

The gate electrode 134 may be arranged in the third direction D3. More particularly, a centerline of the gate electrode 134 may be arranged in the third direction D3.

FIG. 3B is a schematic partially enlarged plan view of a semiconductor device according to example embodiments. FIG. 3B illustrates an enlarged view of region ‘A’ in FIG. 1.

Referring to FIG. 3B, the semiconductor device of an embodiment may have characteristics the same as or similar to those described above with reference to FIG. 3A, except that the first edge L₁ and the second edge L₂ are orthogonal in the first and second corner regions R1 and R2 and the first edge L₁ and the first active edge M₁ are orthogonal in the intersection region Rs.

In the present embodiment, the first edge L₁ may extend straight in the second direction D2, and the second edge L₂ may extend straight in the first direction D1. Accordingly, in each of the first and second corner regions R1 and R2, the first edge L₁ and the second edge L₂ may intersect (e.g., orthogonally) when viewed in plan view. In addition, in the intersection region Rs, the first edge L₁ may perpendicularly intersect the first active edge M1 extending straight in the first direction D1.

FIGS. 4A to 6B are schematic plan views and cross-sectional views illustrating a method of manufacturing a semiconductor device according to example embodiments.

Specifically, FIGS. 4A to 6A are schematic plan views illustrating a method of manufacturing a semiconductor device according to example embodiments, and FIGS. 4B to 6B are cross-sectional views taken along line III-III′ of FIGS. 4A to 6A, respectively.

Referring to FIGS. 4A and 4B, the substrate 101 may be provided, the active region 105 may be formed within the substrate 101, and the device isolation region 110 may be formed, and a patterned (P) circuit gate dielectric layer 132 and the circuit gate electrode layer 134 may be formed on the substrate 101.

The active region 105 may be formed by forming a mask layer on the substrate 101 and implanting impurities through an ion implantation process.

The device isolation region 110 may be formed by removing a portion of the substrate 101 in the first direction D1, for example using an STI process, to form a trench extending in the first direction D1 and filling the trench with an insulating material. Accordingly, the active regions 105 may be formed to be spaced apart from each other in the second direction D2, perpendicular to the first direction D1. The upper surface of the active region 105 may be exposed through a chemical mechanical polishing (CMP) process, and thus, the upper surface of the active region 105 and the upper surface of the device isolation region 110 may be substantially coplanar.

The circuit gate dielectric layer 132 and the circuit gate electrode layer 134 may be sequentially formed on the substrate 101. The circuit gate dielectric layer 132 and the circuit gate electrode layer 134 may be formed using, for example, atomic layer deposition (ALD) or chemical vapor deposition (CVD). The circuit gate dielectric layer 132 may be formed of silicon oxide, and the circuit gate electrode layer 134 may be formed of at least one of polycrystalline silicon or a metal silicide layer, but is not limited thereto.

The pattern P of the circuit gate dielectric layer 132 and the circuit gate electrode layer 134 may be formed through etching. The pattern P may be formed by first forming a mask layer on the circuit gate electrode layer 134 in a direction, parallel to the third direction D3, which is perpendicular to the first direction D1 and the second direction D2, and then removing the exposed circuit gate electrode layer 134 to a lower surface of the circuit gate dielectric layer 132 through dry etching. As illustrated in FIG. 4A, the pattern P may be formed in a wave shape extending in the third direction D3; that is, edges of the pattern P in the third direction D3 may be nonplanar in plan view.

Referring to FIGS. 5A and 5B, the groove H may be formed by etching in the vertical direction Z through the circuit gate dielectric layer 132 and the circuit gate electrode layer 134, and at least partially into the device isolation region 110. The device isolation region 110 may be exposed through the bottom surface of the groove H. A width of the groove H in the third direction D3 may be less than a width of the device isolation region 110 in the third direction D3. In this manner, sections of the circuit gate dielectric layer 132 and circuit gate electrode layer 134 on the active regions 105 may be spaced apart from each other in the third direction D3 by the grooves H.

The groove H may be formed through etching. The groove H may be formed by first forming a mask layer in a direction, parallel to the first direction D1, between the active regions 105 and then removing the exposed circuit gate electrode layer 134 to the bottom level or a level lower than the bottom level through dry etching. The width W of the groove H in the second direction D2 may be formed to have the same size as the third distance d₃ described above with reference to FIG. 3A. Accordingly, the circuit gate electrode layers 134 may be formed to be spaced apart from each other by the groove H in the second direction D2 and spaced apart by the width W (or the third distance d₃) of the groove H. Also, the circuit gate electrode layers 134 may be spaced apart from each other in the third direction D3. In addition, by the etching, a protrusion extending in the first direction D1 may be formed in at least some of the corner regions R1 of the circuit gate electrode layer 134. The protrusion may be formed to have a width narrowing in a direction away from the centerline of the circuit gate electrode layer 134.

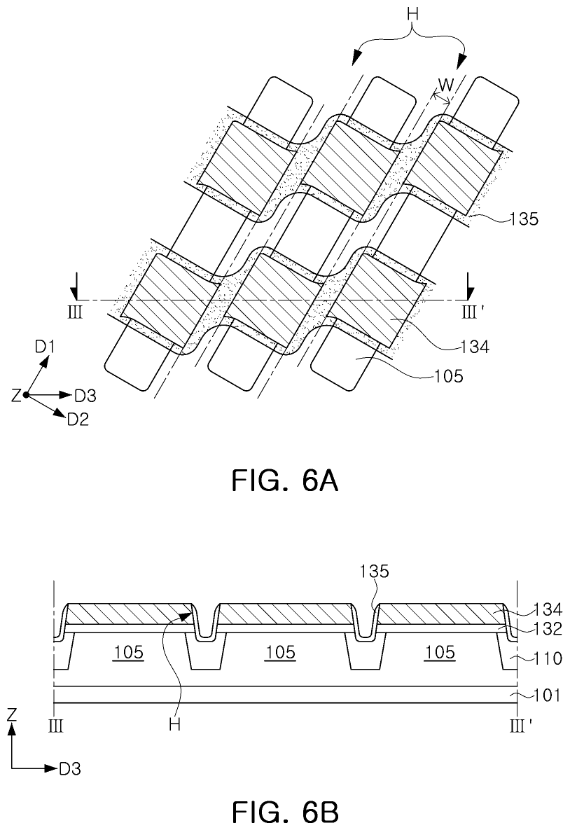

Referring to FIGS. 6A and 6B, the spacer layers 135 may be formed on the sidewalls of the circuit gate dielectric layer 132 and the circuit gate electrode layer 134.

Referring to FIG. 2A together, the spacer layers 135 may be formed by depositing an insulating material and then removing a portion of the insulating material so that the insulating material remains only on the sidewalls of the circuit gate dielectric layer 132 and the circuit gate electrode layer 134 using anisotropic etching.

As illustrated in FIG. 6B, the spacer layers 135 may be deposited on the sidewall H1 and the lower surface H2 of the groove H formed between the active regions 105. As illustrated in FIG. 6A, the spacer layers 135 may be formed to have a wave shape extending in the third direction D3.

Next, referring to FIGS. 1 and 2A together, impurities may be implanted into the substrate 101 on both sides of the spacer layers 135, for example through an ion implantation process, to form the source/drain regions 120, thereby manufacturing the semiconductor device 100 of FIG. 2A.

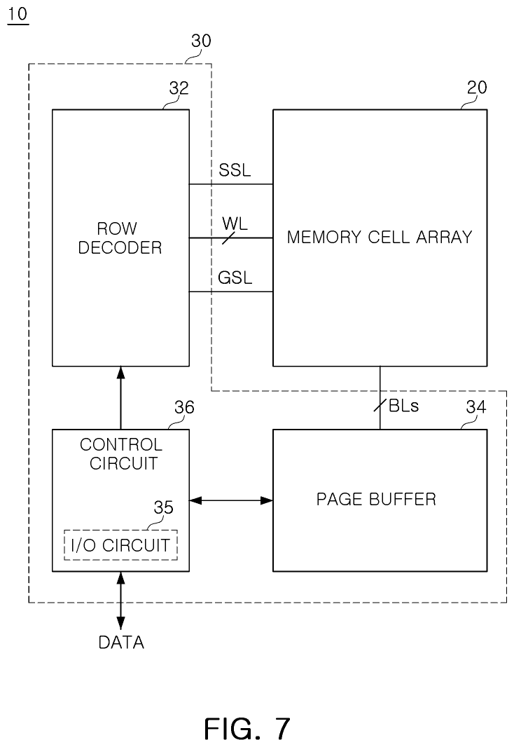

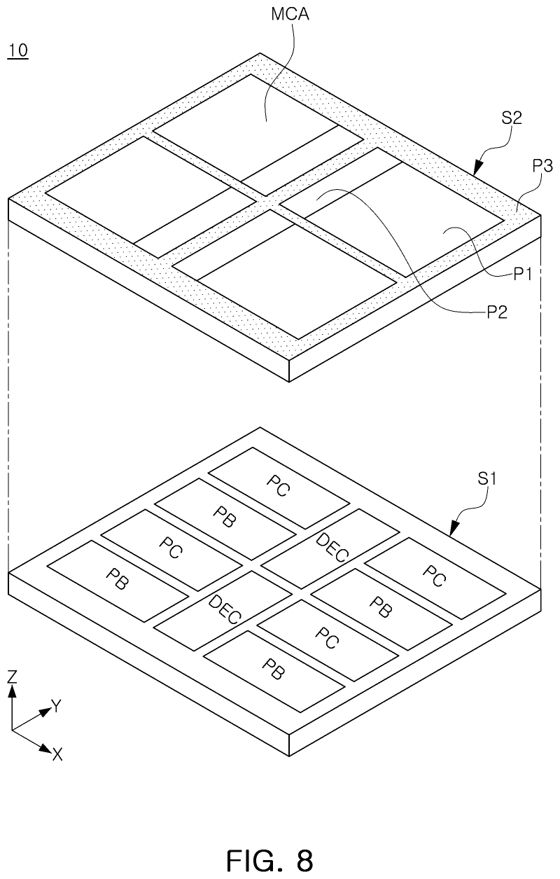

FIG. 7 is a schematic block diagram of a semiconductor device according to example embodiments.

Referring to FIG. 7, a semiconductor device 10 may be a semiconductor memory device including a memory cell array 20 and a control logic 30.

The memory cell array 20 may include a plurality of memory blocks, and each memory block may include a plurality of memory cells. The plurality of memory cells may be connected to a row decoder 32 through a string select line SSL, a plurality of word lines WLs, and a ground select line GSL, and may be connected to a page buffer 34 through a plurality of bit lines BLs. In example embodiments, a plurality of memory cells arranged in the same row may be connected to the same word line WL, and a plurality of memory cells arranged in the same column may be connected to the same bit line BL, with rows intersecting (e.g., orthogonally) columns in the memory cell array 20.

The control logic 30 may include the row decoder 32, the page buffer 34, and a control circuit 36.

The row decoder 32 may decode an input address to generate and transmit driving signals of the word line WL. The row decoder 32 may provide a word line voltage generated by a voltage generating circuit in the control circuit 36 to a selected word line WL and unselected word lines WLs in response to the control of the control circuit 36.

The page buffer 34 may be connected to the memory cell array 20 through the bit lines BLs and may read information stored in the memory cells. Depending on an operation mode, the page buffer 34 may temporarily store data to be stored in the memory cells or detect data stored in the memory cells. The page buffer 34 may include a column decoder and a sense amplifier. The column decoder may selectively activate the bit lines BLs of the memory cell array 20, and the sense amplifier may detect a voltage of the bit line BL selected by the column decoder during a read operation to read data stored in a selected memory cell. The semiconductor device 100 described above with reference to FIG. 1 may be a semiconductor device that forms at least a portion of the page buffer 34.

The control circuit 36 may control one or more operations of the row decoder 32 and the page buffer 34. The control circuit 36 may receive a control signal and an external voltage transmitted from an external source and operate according to the received control signal. The control circuit 36 may include a voltage generating circuit generating voltages necessary for an internal operation, for example, a program voltage, a read voltage, an erase voltage, etc., using an external voltage. The control circuit 36 may control read, write, and/or erase operations in response to the control signals.

The control circuit 36 may include an input/output (I/O) circuit 35. The I/O circuit 35 may be internally connected to the page buffer 34 and externally to a host to input and output data. The I/O circuit 35 may receive data DATA and transmit the data DATA to the page buffer 34 during a program (i.e., write) operation, and output data DATA received from the page buffer 34 externally during a read operation.

FIG. 8 is a perspective schematic layout diagram illustrating a semiconductor device according to example embodiments.

Referring to FIG. 8, the semiconductor device 10 may include first and second semiconductor structures S1 and S2 stacked in a vertical (Z) direction. The first semiconductor structure S1 may be a peripheral circuit structure and may include a row decoder DEC, a page buffer PB, and other peripheral circuits PC. The second semiconductor structure S2 may be a memory cell structure and may include a plurality of memory cell arrays MCA.

In the first semiconductor structure S1, the row decoder DEC may decode an input address to generate and transmit driving signals of the word line. The page buffer PB may be connected to the memory cell arrays MCA through the bit lines and may read information stored in the memory cells. As described above with reference to FIG. 7, the semiconductor device 100 described above with reference to FIG. 1 may be a semiconductor device that constitutes the page buffer PB. Other peripheral circuits PC may be regions including a control logic and a voltage generator, and may include, for example, a latch circuit, a cache circuit, and/or a sense amplifier. The first region P1 may further include a separate pad region, in which case the pad region may include an electrostatic discharge (ESD) device or a data I/O circuit.

At least some of the various circuit regions (DEC, PB, and PC) of the first semiconductor structure S1 may be disposed below the memory cell arrays MCA of the second semiconductor structure S2. For example, the page buffer PB and/or other peripheral circuits PC may be arranged below the memory cell arrays MCA and overlap the memory cell arrays MCA.

However, according to embodiments, the circuits included in the first semiconductor structure S1 and arrangement forms may vary, and accordingly, the circuits disposed to overlap the memory cell arrays MCA may also vary. The term “overlap” (or “overlapping,” or like terms), as may be used herein, is intended to broadly refer to a first element that intersects with at least a portion of a second element in the vertical direction (i.e., the Z direction), but does not require that the first and second elements be completely aligned with one another in a horizontal plane (i.e., in the first direction D1, the second direction D and/or the third direction D3).

The second semiconductor structure S2 may have first to third regions P1, P2, and P3. The first region P1 may be the memory cell arrays MCA, the second region P2 may be a connection region, and the third region P3 may be an outer (i.e., peripheral) region adjacent to the first and second regions P1 and P2. The first region P1 may be a region in which memory cells are arranged, and the second region P2 may be a region for electrically connecting word lines to the circuit regions (DEC, PB, and PC) of the first semiconductor structure S1.

In the second semiconductor structure S2, the memory cell arrays MCAs may be arranged to be spaced apart laterally (i.e., in the X direction and/or Y direction) from each other, and the number and arrangement form of the memory cell arrays MCAs arranged in the second semiconductor structure S2 may vary.

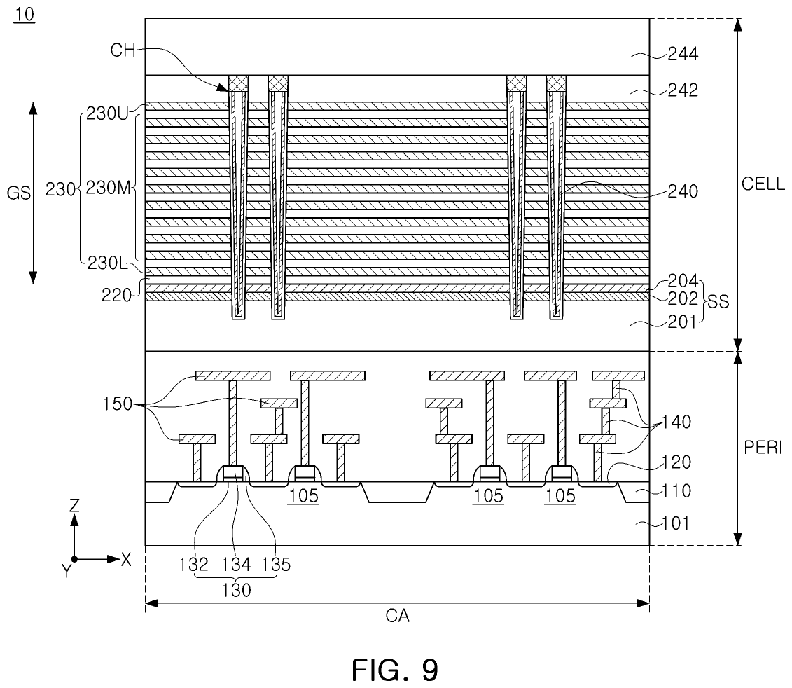

FIG. 9 is a schematic plan view of a semiconductor device according to example embodiments.

Referring to FIG. 9, the semiconductor device 10 may include a peripheral circuit structure PERI (or a ‘peripheral circuit region’) including a substrate 101, and a memory cell structure CELL (or a ‘memory cell region’) including a plate layer 201. As illustrated in FIG. 9, the semiconductor device 10 may include a cell region CA.

The peripheral circuit structure PERI and the memory cell structure CELL may be regions corresponding to the first and second semiconductor structures S1 and S2, respectively, described above with reference to FIG. 8. The memory cell structure CELL may be disposed vertically (i.e. in the Z direction) on the peripheral circuit structure PERI. In example embodiments, conversely, the memory cell structure CELL may be disposed below the peripheral circuit structure PERI in the Z direction.

The peripheral circuit structure PERI may be a region including the semiconductor device 100 described above with reference to FIGS. 1, 2A, and 2B.

The memory cell structure CELL may include a source structure SS, gate electrodes 230 stacked vertically on the source structure SS to form a gate structure GS, interlayer insulating layers 220 alternately stacked with the gate electrodes 230 (i.e., between adjacent gate electrodes 230), channel structures CH configured to pass vertically through the gate structure GS in the cell region CA, and first and second cell region insulating layers 242 and 244 covering the gate electrodes 230.

In the memory cell structure CELL, the cell region CA may be a region in which the gate electrodes 230 are vertically stacked and the channel structures CH are arranged, and may be a region in which memory cells are arranged. The cell region CA may correspond to a partial region of the memory cell array MCA of FIG. 8.

The source structure SS may include the plate layer 201, a first horizontal conductive layer 202 (extending in the X direction and/or Y direction), and a second horizontal conductive layer 204 (extending in the X direction and/or Y direction) sequentially stacked in the vertical direction in the cell region CA. However, in example embodiments, the number of conductive layers forming the source structure SS may vary.

The plate layer 201 may have the shape of a plate (i.e., planar) and may function as at least a portion of a common source line of the semiconductor device 10. The plate layer 201 may have an upper surface extending in the X- and Y-directions. The plate layer 201 may include a conductive material. For example, the plate layer 201 may include a semiconductor material, such as a group IV semiconductor, a group III-V compound semiconductor, or a group II-VI compound semiconductor. For example, the group IV semiconductor may include silicon, germanium, or silicon-germanium. The plate layer 201 may further include impurities. The plate layer 201 may be provided, for example, as a polycrystalline semiconductor layer, such as a polycrystalline silicon layer, or an epitaxial layer.

The first and second horizontal conductive layers 202 and 204 may be sequentially stacked and disposed on the upper surface of the plate layer 201 in the cell region CA. In a connection region not shown, the first horizontal conductive layer 202 may not extend to the connection region, and the second horizontal conductive layer 204 may extend to the connection region. The first horizontal conductive layer 202 may function as a portion of a common source line of the semiconductor device 10, and may function, for example, as a common source line together with the plate layer 201.

The first and second horizontal conductive layers 202 and 204 may include a semiconductor material, for example, polycrystalline silicon. In this case, at least the first horizontal conductive layer 202 may be a layer doped with impurities of the same conductivity type as that of the plate layer 201, and the second horizontal conductive layer 204 may be a doped layer or may be a layer including impurities diffused from the first horizontal conductive layer 202. However, the material of the second horizontal conductive layer 204 is not limited to the semiconductor material, and may be replaced with an insulating layer.

The gate electrodes 230 may be stacked to be vertically spaced apart from each other by the interlayer insulating layers 220 on the plate layer 201 and form the gate structure GS together with the interlayer insulating layers 220. In an example embodiment, the gate structure GS may include a plurality of vertically stacked structures.

The gate electrodes 230 may include a gate electrode (not shown) disposed on the second cell region insulating layer 244 and forming string selection transistors, an upper gate electrode 230U forming an erase transistor, memory gate electrodes 230M forming a plurality of memory cells, and lower gate electrodes 230L forming an erase transistor, and a ground selection transistor. The number of memory gate electrodes 230M forming memory cells may be determined according to the capacity of the semiconductor device 10.

The gate electrodes 230 may include a metal material, such as tungsten (W). According to embodiments, the gate electrodes 230 may include polycrystalline silicon or metal silicide material. The gate electrodes 230 may entirely include the same material. In example embodiments, the gate electrodes 230 may further include a diffusion barrier, and the diffusion barrier may include, for example, tungsten nitride (WN), tantalum nitride (TaN), titanium nitride (TIN), or combinations thereof.

The interlayer insulating layers 220 may be disposed between the gate electrodes 230. Like the gate electrodes 230, the interlayer insulating layers 220 may be arranged to be spaced apart from each other in a direction, perpendicular to the upper surface of the plate layer 201 and extending in the X-direction. The interlayer insulating layers 220 may include an insulating material, such as silicon oxide or silicon nitride.

The channel structures CH may extend in the Z-direction through the gate electrodes 230 excluding the gate electrode (not explicitly shown) which may be disposed on the second cell region insulating layer 244, and be connected to the plate layer 201. The channel structures CH may each form one memory cell string, and may be arranged to be spaced apart from each other in rows and columns on the plate layer 201 in the cell region CA. The channel structures CH may be arranged to form a grid pattern or may be arranged in a zigzag shape in one direction in the X-Y (i.e., horizontal) plane. The channel structures CH may have a pillar shape and may have inclined side surfaces, such that a horizontal width of the channel structures decreases as the channel structures extend vertically (i.e., in the Z direction) toward the plate layer 201. At least some of the channel structures CH, including the channel structures CH disposed at the end of the cell region CA, may be dummy channel structures. Each of the channel structures CH may include a channel layer 240 disposed in a lower channel hole, a gate dielectric layer, a channel buried insulating layer, and a channel pad. The channel structures CH may include a plurality of vertically stacked channel structures.

The connection region (not explicitly shown) may be a region in which the gate electrodes 230 extend to have different lengths and may correspond to a region for electrically connecting the memory cells to the peripheral circuit structure PERI. The connection region may be disposed at one or more ends of the first region R1 in at least one direction, for example, the X-direction.

By patterning and etching the gate to have a predetermined shape on the diagonally arranged active region, the semiconductor device having increased integration and reliability may be provided.

While example embodiments have been shown and described above, it will be apparent to those skilled in the art that modifications and variations could be made without departing from the scope of the present inventive concept as defined by the appended claims.

What is claimed is:

1. A semiconductor device, comprising:
a substrate;
active regions extending on the substrate in a first direction parallel to an upper surface of the substrate, the active regions spaced apart from each other in a second direction parallel to the upper surface of the substrate and perpendicular to the first direction, and arranged in a third direction parallel to the upper surface of the substrate and oblique to the first direction and second direction; and
gate electrodes on the active regions, each of the gate electrodes including a first edge extending in the second direction, a second edge extending in the first direction, and a corner region defined by an intersection of the first edge and the second edge,
wherein the corner region includes a protrusion having a width narrowing in a direction away from a center of each of the gate electrodes when viewed in plan view.

2. The semiconductor device of claim 1, wherein the first edge has a first curved portion in the corner region, and a tangent line of the first edge in the corner region forms an acute angle with the second edge.

3. The semiconductor device of claim 2, wherein
the active regions have a first active edge extending in the first direction,
the gate electrodes have an intersection region in which the first edge and the first active edge intersect,
the first edge includes a second curved portion having a second slope less than a first slope of the first curved portion in the intersection region, and
the first edge and the first active edge form an angle of 90 degrees or greater in the intersection region.

4. The semiconductor device of claim 1, wherein the intersection of the first edge and the second edge forms a right angle in the corner region.

5. The semiconductor device of claim 1, wherein the active regions are spaced apart from each other in the second direction by about 40 nm to about 60 nm.

6. The semiconductor device of claim 1, wherein the active regions are spaced apart from each other in the second direction by about 45 nm to about 55 nm.

7. The semiconductor device of claim 1, wherein the second edge is configured to extend outside of the active region in the second direction by about 10 nm to 20 nm.

8. The semiconductor device of claim 7, wherein respective second edges of adjacent gate electrodes are spaced apart from each other in the second direction by about 15 nm to about 25 nm.

9. The semiconductor device of claim 1, further comprising:
a spacer layer extending around sides of the gate electrodes,
wherein the spacer layer includes straight portions parallel to the first edge at the top of each of the active regions and curved portions connected to the straight portions between the active regions when viewed in plan view.

10. The semiconductor device of claim 9, wherein the gate electrodes are configured in the third direction, and the spacer layer extends in the third direction.

11. A semiconductor device, comprising:
a substrate;
active regions extending on the substrate in a first direction parallel to an upper surface of the substrate, the active regions spaced apart from each other in a second direction parallel to the upper surface of the substrate and perpendicular to the first direction, and arranged in a third direction parallel to the upper surface of the substrate and oblique to the first direction and second direction;
gate electrodes arranged in the third direction on the active regions;
a groove between the gate electrodes adjacent to each other in the third direction and extending in the first direction; and
a spacer layer filling at least a portion of the groove and extending around sides of the gate electrodes.

12. The semiconductor device of claim 11, wherein a horizontal width of an upper portion of the groove in the second direction is about 15 nm to about 25 nm.

13. The semiconductor device of claim 11, wherein a bottom level of the groove relative to the upper surface of the substrate is lower than a top level of the active regions.

14. The semiconductor device of claim 11, wherein the spacer layer is on a side surface and a lower surface of the groove.

15. The semiconductor device of claim 14, wherein the spacer layer extends in the third direction, and the spacer layer has a wave shape when viewed in plan view.

16. The semiconductor device of claim 11, wherein at least a portion of the lower surface of the groove is exposed, and the spacer layer is on side surfaces of the groove and spaced apart from one another in the second direction.

17. A semiconductor memory device, comprising:
a memory cell region including memory cells on a plate layer; and
a peripheral circuit region adjacent to the memory cell region and including transistors electrically connected to the memory cells,
wherein the transistors include:
active regions extending in a first direction on a substrate parallel to an upper surface of the substrate, the active regions spaced apart from each other in a second direction parallel to the upper surface of the substrate and perpendicular to the first direction, and configured in a third direction parallel to the upper surface of the substrate and oblique to the first direction and second direction;
gate electrodes on the active regions, each of the gate electrodes including a corner region having at least one protrusion extending the first direction; and
a spacer layer extending around the gate electrodes and having a wave shape when viewed in plan view.

18. The semiconductor memory device of claim 17, wherein the at least one protrusion of each of the gate electrodes has a width that decreases in the first direction as the at least one protrusion extends away from a center of the gate electrodes.

19. The semiconductor memory device of claim 17, wherein the transistors constitute at least a portion of the page buffer circuit.

20. The semiconductor memory device of claim 17, wherein the plate layer is on a level higher than that of the substrate relative to the upper surface of the substrate being a base reference layer.
